(19) United States
(12) Patent Application Publication
(10) Pub. No.: US 2025/0146129 A1
(43) Pub. Date: May 8, 2025

(54) SEMICONDUCTOR MANUFACTURING FACILITY AND SHOWER HEAD COATING METHOD USING THE SAME

(71) Applicant: SEMES CO., LTD., Cheonan-si (KR)

(72) Inventors: Yeong Gyu KIM, Cheonan-si (KR); Guen Do PARK, Cheonan-si (KR)

(73) Assignee: SEMES CO., LTD., Cheonan-si (KR)

(21) Appl. No.: 18/907,446

(22) Filed: Oct. 4, 2024

(30) Foreign Application Priority Data
Nov. 8, 2023 (KR) 10-2023-0153581

(51) Int. Cl. C23C 16/448; C23C 16/24; C23C 16/40; C23C 16/455; C23C 16/458; C23C 16/50; C23C 16/52

(52) U.S. Cl. CPC C23C 16/4485; C23C 16/24; C23C 16/401; C23C 16/45565; C23C 16/4583; C23C 16/50; C23C 16/52

(57) ABSTRACT

Disclosed are a semiconductor manufacturing facility and a shower head coating method using the same. The semiconductor manufacturing facility includes an index block, a processing block including a substrate processing apparatus, and a substrate transferring block. The substrate processing apparatus includes a chamber including a processing space defined therein, a substrate support unit disposed in the processing space and including a first heating member configured to heat the substrate coated with the precursor, a gas supply unit configured to supply gas to the processing space, a plasma generation unit configured to convert the supplied gas into plasma, a shower head configured to supply the supplied gas to the processing space, and a controller. The controller controls the first heating member to heat the substrate supported by the substrate support unit so that the precursor applied to the substrate is vaporized and a coating layer is formed on the shower head.

### CROSS-REFERENCE TO RELATED APPLICATION(S)

This application claims priority under 35 U.S.C. § 119 to Korean Patent Application No. 10-2023-0153581, filed on Nov. 8, 2023 in the Korean Intellectual Property Office, the disclosure of which is incorporated by reference herein in its entirety.

### BACKGROUND OF THE INVENTION

### Field of the Invention

The present invention relates to a semiconductor manufacturing facility and a shower head coating method using the same. More particularly, the present invention relates to a method of coating a shower head by applying a precursor to a substrate and vaporizing the applied precursor.

### Description of the Related Art

A process for manufacturing semiconductor devices or liquid crystal displays employs a substrate processing apparatus in which plasma is generated in a chamber reduced in pressure to a predetermined vacuum pressure and then is applied to a substrate, such as a semiconductor wafer or a glass substrate for a liquid crystal display, thereby performing predetermined processing, such as a deposition process, an etching process, or an ashing process.

In general, an apparatus for processing a substrate using plasma is provided with a shower head. The shower head may be used as an upper electrode. The shower head may receive gas required for a process, and may generate a radio frequency electric field while evenly spraying the gas into a processing space in a chamber, thereby generating plasma in the processing space in the chamber.

In such a process using plasma, the shower head is continuously exposed to the plasma, which entails a problem that the surface of the shower head is etched by the plasma, leading to increase in the volume of the processing space in the chamber and change in the size of gas supply holes in the shower head.

### SUMMARY OF THE INVENTION

Therefore, the present invention has been made in view of the above problems, and it is an object of the present invention to provide a semiconductor manufacturing facility capable of preventing damage to a shower head due to plasma and a shower head coating method using the same.

The objects to be accomplished by the invention are not limited to the above-mentioned object, and other objects not mentioned herein will be clearly understood by those skilled in the art from the following description.

In accordance with an aspect of the present invention, the above and other objects can be accomplished by the provision of a semiconductor manufacturing facility including an index block including a carrier configured to store a substrate coated with a precursor, a processing block including a substrate processing apparatus configured to perform processing on the substrate, and a substrate transferring block including a substrate transferring robot configured to load or unload the substrate. The substrate processing apparatus includes a chamber including a processing space defined therein, a substrate support unit disposed in the processing space and including a first heating member configured to support and heat the substrate coated with the precursor, a gas supply unit configured to supply gas to the processing space, a plasma generation unit configured to convert the supplied gas into plasma, a shower head configured to supply the supplied gas to the processing space, and a controller configured to control the gas supply unit and the plasma generation unit. The controller controls the first heating member to heat the substrate supported by the substrate support unit so that the precursor applied to the substrate is vaporized and a coating layer is formed on the shower head.

In one embodiment, the shower head may include a second heating member.

In one embodiment, the controller may control the second heating member of the shower head to apply heat to the coating layer formed on the shower head.

In one embodiment, the first heating member of the substrate support unit may heat the substrate to 200° C. to 500° C., and the second heating member of the shower head may heat the coating layer formed on the shower head to 200° C. to 500° C.

In one embodiment, the coating layer formed on the shower head may be a silicon film or a silicon oxide film.

In one embodiment, the substrate support unit may further include a driving unit and a lift pin assembly configured to raise and lower the substrate.

In one embodiment, the controller may control the driving unit to raise the substrate coated with the precursor toward the shower head, and may control the first heating member to vaporize the precursor applied to the substrate raised toward the shower head.

In one embodiment, the precursor may include silane or siloxane.

In one embodiment, the precursor including silane may be a precursor represented by the following Formula 1.

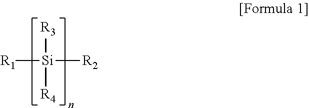

Here, R1, R2, R3, and R4 may each be independently selected from the group consisting of H, OH, and a C1-C6 alkyl or alkenyl group, and n may be in the range of 1 to 2,000 (1≤n≤2,000).

In one embodiment, the precursor including siloxane may be a precursor represented by the following Formula 2.

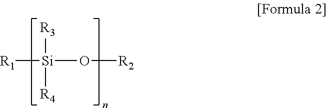

Here, R1, R2, R3, and R4 may each be independently selected from the group consisting of H, OH, and a C1-C6 alkyl or alkenyl group, and n may be in the range of 1 to 2,000 (1≤n≤2,000).

In accordance with another aspect of the present invention, there is provided a shower head coating method including a precursor application step of applying a precursor to a substrate, a placement step of placing the substrate coated with the precursor in a processing space in a chamber, a heat/pressure application step of applying heat and pressure to the substrate coated with the precursor, a coating layer forming step of vaporizing the precursor to form a coating layer on a shower head disposed so as to face the substrate, and a film quality improvement step of heating the shower head to apply heat to the coating layer.

In one embodiment, the precursor in the precursor application step may include silane or siloxane.

In one embodiment, the precursor including silane may be a precursor represented by the following Formula 1.

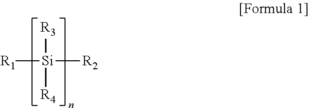

Here, R1, R2, R3, and R4 may each be independently selected from the group consisting of H, OH, and a C1-C6 alkyl or alkenyl group, and n may be in the range of 1 to 2,000 (1≤n≤2,000).

In one embodiment, the precursor including siloxane may be a precursor represented by the following Formula 2.

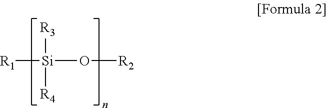

Here, R1, R2, R3, and R4 may each be independently selected from the group consisting of H, OH, and a C1-C6 alkyl or alkenyl group, and n may be in the range of 1 to 2,000 (1≤n≤2,000).

In one embodiment, the placement step may include a movement step moving the substrate coated with the precursor to a position facing the shower head.

In one embodiment, in the heat/pressure application step, the heat applied to the substrate may range from 200° C. to 500° C., and the pressure applied to the substrate may range from normal pressure to 0.01 torr.

In one embodiment, the coating layer formed in the coating layer forming step may be a silicon film or a silicon oxide film.

In one embodiment, the coating layer may have a thickness of 1 μm to 1 mm.

In one embodiment, in the film quality improvement step, the coating layer may be heated to 200° C. to 500° C.

In accordance with a further aspect of the present invention, there is provided a semiconductor manufacturing facility including a carrier configured to store a substrate having a precursor applied to an upper surface thereof, an index block including a load port configured to allow the carrier storing the substrate to be seated thereon and an index frame provided with an index robot configured to withdraw the substrate from the carrier seated on the load port, a load lock chamber configured to temporarily store the substrate transferred from the index robot, a processing block including a substrate processing apparatus configured to perform processing on the substrate, and a substrate transferring block including a substrate transferring robot configured to load the substrate transferred from the load lock chamber into the substrate processing apparatus or to transfer the substrate unloaded from the substrate processing apparatus to the load lock chamber. The substrate processing apparatus includes a chamber including a processing space defined therein, a substrate support unit disposed in the processing space and configured to support the substrate coated with the precursor transferred from the substrate transferring robot, a first heating member configured to heat the substrate coated with the precursor, a gas supply unit configured to supply gas to the processing space, a plasma generation unit configured to convert the supplied gas into plasma, a shower head configured to supply the supplied gas to the processing space, a driving unit configured to raise the substrate support unit or the substrate supported on the substrate support unit toward the shower head, and a controller. When the substrate coated with the precursor is transferred to the substrate support unit, the controller controls the driving unit to raise the substrate coated with the precursor toward the shower head, and controls the first heating member so that the precursor applied to the substrate is vaporized and a coating layer is formed on the shower head.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view showing a substrate coating apparatus according to an embodiment of the present invention;

FIG. 2 is a view showing a semiconductor manufacturing facility according to an embodiment of the present invention;

FIG. 3 is a view showing a substrate processing apparatus according to an embodiment of the present invention;

FIGS. 4 and 5 are flowcharts showing a a shower head coating method according to an embodiment of the present invention;

FIG. 6 is a view showing a substrate processing apparatus according to another embodiment of the present invention; and

FIG. 7 is a flowchart showing a shower head coating method according to another embodiment of the present invention.

### DETAILED DESCRIPTION OF THE INVENTION

Hereinafter, embodiments of the present invention will be described in detail with reference to the accompanying drawings so that those skilled in the art can easily carry out the embodiments. The present invention may, however, be embodied in many different forms, and should not be construed as being limited to the embodiments set forth herein.

In the following description of the embodiments of the present invention, a detailed description of known functions or configurations incorporated herein will be omitted when it may unnecessarily obscure the subject matter of the present invention. Throughout the drawings, parts performing similar functions and operations are denoted by the same reference numerals.

At least some of the terms used in this specification are terms defined taking into consideration the functions obtained in accordance with the present invention, and may be changed in accordance with the intention of users or operators or usual practice. Therefore, the definitions of these terms should be determined based on the total content of this specification.

As used herein, singular forms may include plural forms, unless the context clearly indicates otherwise. Additionally, the term “comprise”, “include”, or “have” described herein should be interpreted not to exclude other elements but to further include such other elements unless mentioned otherwise.

In the drawings, the sizes or shapes of elements and thicknesses of lines may be exaggerated for clarity and convenience of description.

Hereinafter, embodiments of the present invention will be described in detail with reference to the accompanying drawings, and the same or similar elements are denoted by the same reference numerals even though they are depicted in different drawings, and redundant descriptions thereof will be omitted.

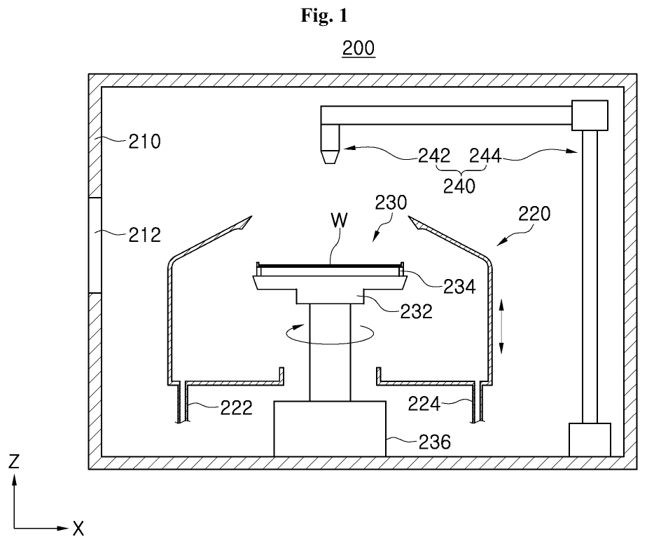

FIG. 1 is a view showing a substrate coating apparatus according to an embodiment of the present invention.

Referring to FIG. 1, the substrate coating apparatus 200 according to the embodiment of the present invention is a spin coating apparatus, and may include a housing 210, a processing vessel 220, a substrate support unit 230, and a spray unit 240.

The housing 210 may be formed in a rectangular casing shape having a processing space defined therein. The housing 210 may include an opening 212 formed in a sidewall thereof. The opening 212 may function as a passage through which a substrate W enters the housing 210. The housing 210 may be provided with a door configured to open or close the opening 212.

The processing vessel 220 may be formed in a cup shape that includes a processing space defined therein and an open top. The processing vessel 220, which receives a liquid, such as a pre-wet solution or a photoresist, from the substrate W, may be provided on a lower surface thereof with a discharge port 222 configured to discharge the collected liquid and an exhaust port 224 configured to discharge gas in the processing vessel 220. The processing vessel 220 may be configured to be movable upward and downward.

The substrate support unit 230 may be disposed in the processing space in the processing vessel 220. The substrate support unit 230 may include a spin chuck 232 in order to rotate the substrate W. The spin chuck 232 may be provided as a substrate support member 232 configured to support the substrate W. The spin chuck 232 may be formed to have a circular plate shape. In an example, the spin chuck 232 may be provided with a plurality of chuck pins 234 configured to hold a side portion of the substrate W. In an example, the chuck pins 234 may be disposed at regular intervals along the periphery of the substrate W. The number of chuck pins 234 and the shape and position thereof may be variously changed.

The spin chuck 232 may be configured to rotatable at a desired speed by a rotary drive member 236. For example, the rotary drive member 236 may be a motor with a variable rotational speed. In addition, the rotary drive member 236 may be provided with an ascending/descending mechanism such as a cylinder, and the spin chuck 232 may be configured to be raised and lowered by the ascending/descending mechanism.

The spray unit 240 may include a nozzle 242 configured to supply a treatment liquid to the substrate and a nozzle driver 244 configured to drive the nozzle 242.

The nozzle driver 244 may move the nozzle 242 to a process position and a standby position. Here, the process position may be a position at which the nozzle 242 faces the substrate W supported on the spin chuck 232, and the standby position may be a position deviated from the process position of the nozzle 242.

The nozzle 242 may supply a precursor to the substrate W. The precursor according to the embodiment of the present invention may be a precursor including silane or siloxane. The precursor including silane is represented by the following Formula 1.

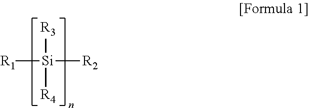

Here, R1, R2, R3, and R4 may each be independently selected from the group consisting of H, OH, and a C1-C6 alkyl or alkenyl group. In addition, n may be in the range of 1 to 2,000 (1≤n≤2,000).

The precursor including siloxane is represented by the following Formula 2.

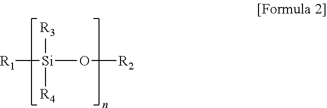

Here, R1, R2, R3, and R4 may each be independently selected from the group consisting of H, OH, and a C1-C6 alkyl or alkenyl group. In addition, n may be in the range of 1 to 2,000 (1≤n≤2,000).

Although the present invention has been described as using the spin coating apparatus in order to apply a precursor to the substrate W, the invention is not limited thereto. In an example, the substrate W may be processed to have a space defined therein, a precursor having low viscosity may be poured into the space in the substrate W, and then the substrate W may be placed in a processing space in a substrate processing apparatus 100 to be described later.

According to an embodiment of the present invention, the substrate W coated with the precursor by the substrate coating apparatus 200 may be moved to a substrate processing apparatus 100 of a semiconductor manufacturing facility 1 to be described later.

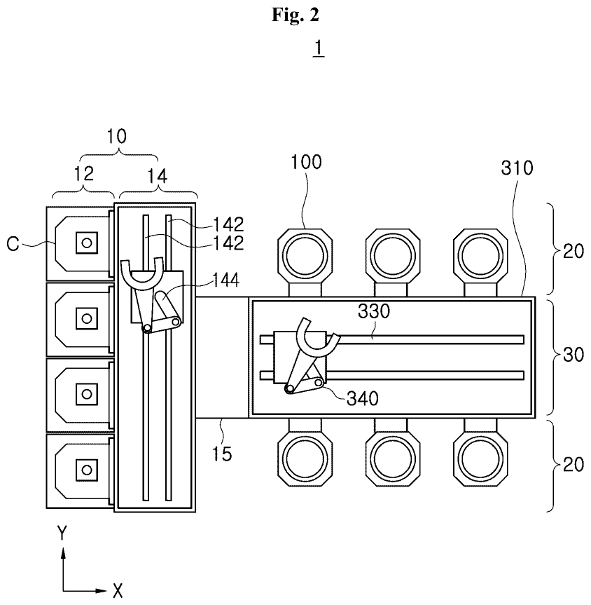

FIG. 2 is a view showing the configuration of a semiconductor manufacturing facility according to an embodiment of the present invention. According to an embodiment of the present invention, the substrate W coated with the precursor by the substrate coating apparatus 200 may be placed in the semiconductor manufacturing facility 1.

Referring to FIG. 2, the semiconductor manufacturing facility 1 may include an index block 10, a processing block 20, and a substrate transferring block 30 configured to transfer a substrate between the index block 10 and the processing block 20. According to an embodiment of the present invention, the index block 10 and the processing block 20 may be sequentially disposed in a line.

The index block 10 may include a load port 12, on which a carrier C storing a substrate is seated, and an index frame 14, which takes the substrate out of the carrier C seated on the load port 12 or transfers a substrate having undergone processing into the carrier C. The load port 12 is located opposite the processing block 20 with respect to the index frame 14. A plurality of carriers C storing substrates may be placed on the load port 12.

The index frame 14 may be provided therein with an index robot 144. The index robot 144 may be formed so as to be movable along a rail 142. The index robot 144 may serve to receive a substrate from the carrier C and transfer the substrate to a load lock chamber 15 configured to temporarily store substrates or to receive a substrate temporarily stored in the load lock chamber 15 and transfer the substrate into the carrier C.

The processing block 20 may be a device in which processing is performed on the substrate. The processing block 20 may include one or more substrate processing apparatuses 100. A plurality of substrate processing apparatuses 100 may be disposed. The respective substrate processing apparatuses 100 may perform the same process or may perform different processes. In an example, some substrate processing apparatuses may perform an etching process on substrates, and other substrate processing apparatuses may perform a cleaning process on the substrates having undergone the etching process. The substrate coated with the precursor may be placed in the processing space in the substrate processing apparatus 100 according to the embodiment of the present invention, and a coating layer may be formed on the shower head.

The substrate transferring block 30 may be disposed adjacent to the processing block 20, and may serve to receive a substrate from the load lock chamber 15 and transfer the substrate to the processing block 20 or to transfer a substrate having undergone processing from the processing block 20 to the load lock chamber 15. The substrate transferring block 30 may include a rail 330 disposed in the direction in which the substrate processing apparatuses 100 are disposed and a substrate transferring robot 340 configured to transfer the substrate while moving along the rail 330. The substrate transferring robot 340 may transfer the substrate while moving in an inner space in a transferring chamber 310.

According to an embodiment of the present invention, after a precursor is applied to the substrate using the substrate coating apparatus 200 shown in FIG. 1, the substrate coated with the precursor may be placed in the substrate processing apparatus 100 of the semiconductor manufacturing facility 1 shown in FIG. 2. In this state, a coating layer may be formed on the shower head by vaporizing the precursor. In order to prevent the precursor from being vaporized while the substrate W coated with the precursor is moved within the semiconductor manufacturing facility 1, the pressure in the semiconductor manufacturing facility 1 may be normal pressure to 0.1 torr.

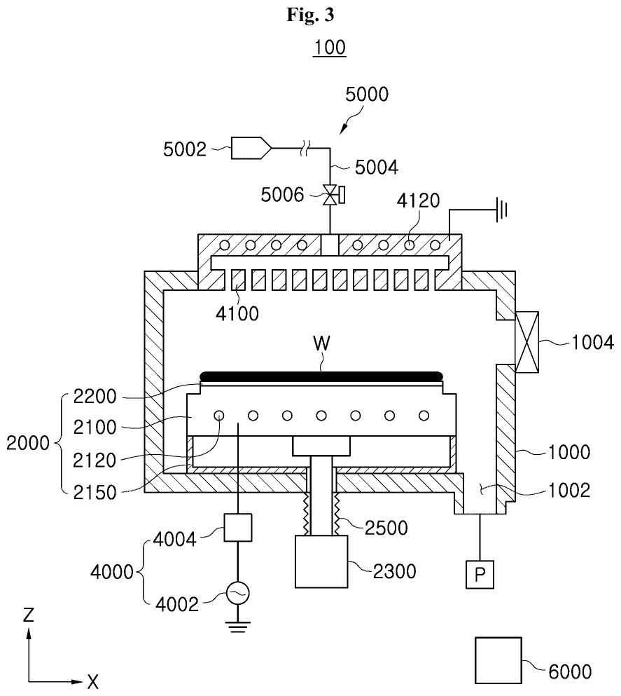

FIG. 3 is a view showing a substrate processing apparatus provided in the processing block according to an embodiment of the present invention.

Referring to FIG. 3, the substrate processing apparatus 100 according to the embodiment of the present invention may be an apparatus using plasma, and may include a chamber 1000, a substrate support unit 2000, a plasma generation unit 4000, a gas supply unit 5000, and a controller 6000.

The chamber 1000 may have a processing space defined therein so as to allow a plasma process to be performed therein. The chamber 1000 may include an exhaust port 1002 formed in a lower side thereof, and the exhaust port 1002 may be connected to an exhaust line on which a pump P is mounted. The exhaust port 1002 may discharge reaction by-products generated during the plasma process and gas remaining in the chamber 1000 to the outside of the chamber 1000 through the exhaust line. In this case, pressure in the inner space in the chamber 1000 may be reduced to a predetermined pressure.

The chamber 1000 may include an opening 1004 formed in the sidewall thereof. The opening 1004 may function as a passage through which a substrate W enters the chamber 1000. The opening 1004 may be configured to be opened and closed by a door assembly.

The substrate support unit 2000 may be disposed in a lower area in the chamber 1000. The substrate support unit 2000 may support the substrate W using electrostatic force. However, this embodiment is not limited thereto. The substrate W may be supported in various ways, as such mechanical clamping or vacuum support.

The substrate support unit 2000 may include a support body 2100 and an electrostatic chuck 2200 disposed on the upper surface of the support body 2100. The electrostatic chuck 2200 may be configured to electrostatically attract and hold the substrate W, and may include a ceramic layer provided with an electrode.

According to an embodiment of the present invention, the substrate support unit 2000 may be provided therein with a first heating member 2120 to maintain the substrate W at a process temperature. The first heating member 2120 may be a heating coil. The first heating member 2120 according to the embodiment of the present invention may heat the substrate to 200° C. to 500° C.

A pedestal 2150 may be provided under the support body 2100 in order to support the support body 2100 and the electrostatic chuck 2200. The pedestal 2150 may be formed in a cylindrical shape having a predetermined height, and may have a space defined therein. A driving unit 2300 may be provided in the pedestal 2150.

The substrate support unit 2000 may include the driving unit 2300. The driving unit 2300 may raise and lower the substrate support unit 2000. The driving unit 2300 may employ a hydraulic cylinder, a pneumatic cylinder, or the like. However, this embodiment is not limited thereto.

A bellows 2500 may be provided on a portion of the driving unit 2300 that extends to the outside of the chamber 1000. The bellows 2500 may have a structure capable of expanding and contracting, and may be provided to surround the driving unit 2300. Accordingly, the interior of the chamber 1000 may be blocked from the outside, and thus the vacuum state in the chamber 1000 may be maintained even when the driving unit 2300 moves vertically.

The plasma generation unit 4000 may generate plasma in the processing space in the chamber 1000. Plasma may be generated in an area above the substrate support unit 2000 in the chamber 1000. The plasma generation unit 4000 according to the embodiment of the present invention may generate plasma in the processing space in the chamber 1000 using a capacitively coupled plasma (CCP) source.

However, this embodiment is not limited thereto. The plasma generation unit 4000 may also generate plasma in the processing space in the chamber 1000 using another type of plasma source, such as an inductively coupled plasma (ICP) source or microwaves.

The plasma generation unit 4000 may include a high-frequency power supply 4002 and a matching device 4004. The high-frequency power supply 4002 may supply high-frequency power to any one of an upper electrode and a lower electrode in order to generate a potential difference between the upper electrode and the lower electrode. Here, the upper electrode may be a shower head 4100, and the lower electrode may be the substrate support unit 2000. The high-frequency power supply 4002 may be connected to the lower electrode, and the upper electrode may be grounded.

The shower head 4100 may be provided in the chamber 1000 so as to vertically oppose the electrostatic chuck 2200. The shower head 4100 may include a plurality of gas spray holes formed therein to evenly spray gas to the interior of the chamber 1000, and may be formed to have a larger diameter than the electrostatic chuck 2200. The shower head 4100 may be provided therein with a second heating member 4120 to heat the shower head 4100. For example, the second heating member 4120 may be a heating coil. According to an embodiment of the present invention, the second heating member 4120 of the shower head 4100 may be heated so that heat is applied to the coating layer formed on the shower head 4100. In this case, the shower head may be in the temperature range of 200° C. to 500° C. According to an embodiment of the present invention, the film quality of the coating layer may be improved by applying heat to the coating layer formed on the shower head 4100 using the second heating member 4120 of the shower head 4100. The shower head 4100 may be made of a material containing a silicon component or a material containing a metal component.

The gas supply unit 5000 may supply gas necessary for the process to the interior of the chamber 1000. The gas supply unit 5000 may include a gas source 5002, a gas supply line 5004, and a gas spray nozzle. The gas supply line 5004 may connect the gas source 5002 to the gas spray nozzle. The gas supply line 5004 may supply gas stored in the gas source 5002 to the gas spray nozzle. A gas supply valve 5006 may be mounted on the gas supply line 5004 in order to open and close the passage of the gas supply line 5004 or to regulate the flow rate of the fluid flowing through the passage.

Although one gas source 5002 and one gas supply valve 5006 are illustrated in FIG. 3, the invention is not limited thereto. The gas supply unit of the present invention may include a plurality of gas sources to supply a plurality of gases to the chamber and a plurality of gas supply valves to independently control supply of the respective gases.

The controller 6000 may comprehensively control the operation of the substrate processing apparatus 100 configured as described above. The controller 6000 may be, for example, a computer, and may include a central processing unit (CPU), random access memory (RAM), read only memory (ROM), and an auxiliary storage device. The CPU may operate on the basis of a program stored in the ROM or the auxiliary storage device or a process condition to control the overall operation of the apparatus. In addition, a computer-readable program necessary for control may be stored in a storage medium. The storage medium may include, for example, a flexible disk, a compact disc (CD), a CD-ROM, a hard disk, a flash memory, a DVD, or the like. The controller 6000 may be provided inside or outside the substrate processing apparatus 100. In the case in which the controller 6000 is provided outside the substrate processing apparatus 100, the controller 6000 may control the substrate processing apparatus 100 using a wired or wireless communication method.

The controller 6000 according to the embodiment of the present invention control such that gas is supplied to the processing space in the chamber 1000 in order to perform a process and the gas is converted into plasma by the plasma generation unit 4000. The controller 6000 may control the operation of the driving unit 2300 of the substrate support unit 2000 to move the substrate W to a position spaced a predetermined distance from the shower head 4100, and may control the first heating member 2120 of the substrate support unit 2000 to apply heat to the substrate W coated with the precursor. In addition, the controller 6000 may control the second heating member 4120 of the shower head 4100 to condense the vaporized precursor, thereby improving the film quality of the coating layer formed on the shower head 4100.

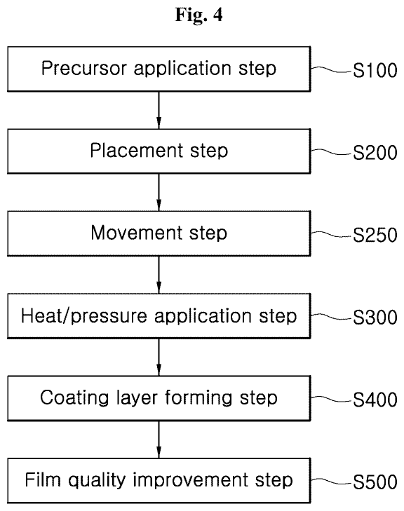

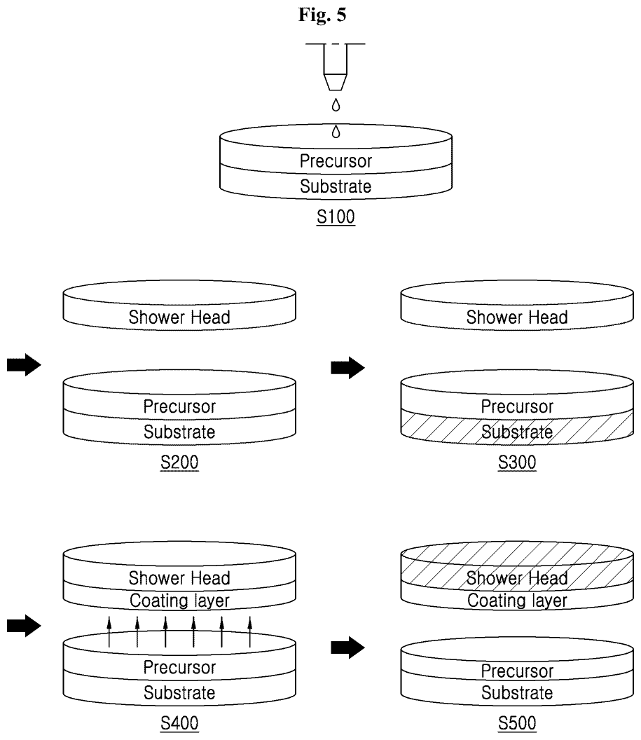

FIGS. 4 and 5 are flowcharts showing a shower head coating method according to an embodiment of the present invention.

Referring to FIGS. 4 and 5, the shower head coating method may include a precursor application step S100 of applying a precursor to a substrate, a placement step S200 of placing the substrate coated with the precursor in a processing space in a chamber, a heat/pressure application step S300 of applying heat and pressure to the substrate coated with the precursor, a coating layer forming step S400 of forming a coating layer on a shower head, and a film quality improvement step S500 of heating the shower head to apply heat to the coating layer.

The precursor application step S100 is a step of applying a precursor to a substrate. The precursor may be a precursor including silane or siloxane. The precursor including silane according to the embodiment of the present invention is a precursor represented by the following Formula 1.

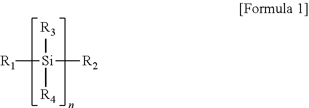

Here, R1, R2, R3, and R4 may each be independently selected from the group consisting of H, OH, and a C1-C6 alkyl or alkenyl group. In addition, n may be in the range of 1 to 2,000 (1≤n≤2,000).

The precursor including siloxane according to the embodiment of the present invention is a precursor represented by the following Formula 2.

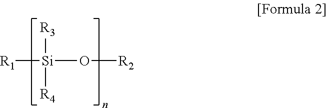

Here, R1, R2, R3, and R4 may each be independently selected from the group consisting of H, OH, and a C1-C6 alkyl or alkenyl group. In addition, n may be in the range of 1 to 2,000 (1≤n≤2,000).

According to an embodiment of the present invention, the substrate coating apparatus may be used to apply a precursor to a substrate. However, the invention is not limited thereto. In an example, the substrate may be processed to have a space defined therein, and a precursor having low viscosity may be poured into the space in the substrate so that the space in the substrate is filled with the precursor. In this case, the substrate coating apparatus may not be used.

The placement step S200 is a step of placing the substrate coated with the precursor in the processing space in the chamber. In this case, the substrate coated with the precursor may be placed in the processing space in the substrate processing apparatus. According to an embodiment of the present invention, the placement step S200 may include a movement step S250 of moving the substrate after placing the substrate in the processing space. In the movement step S250, the substrate coated with the precursor may be moved using the driving unit of the substrate support unit such that the substrate coated with the precursor is disposed at a position spaced a predetermined distance from the shower head.

The heat/pressure application step S300 is a step of applying heat and pressure to the substrate coated with the precursor. In order to apply heat to the substrate, the first heating member of the substrate support unit may be heated. In this case, the substrate may be in the temperature range of 200° C. to 500° C. It is also possible to apply pressure to the substrate simultaneously with applying heat thereto. In order to apply pressure to the substrate, the pressure in the chamber may be controlled. In this case, the pressure applied to the substrate may be controlled to be normal pressure to 0.01 torr. When both heat and pressure are applied to the substrate coated with the precursor, the precursor applied to the substrate may be vaporized.

The coating layer forming step S400 is a step of forming a coating layer on the shower head. The precursor on the substrate coated with the precursor may be vaporized in the heat/pressure application step S300, and the vaporized precursor may be condensed on the surface of the shower head to form a coating layer thereon. The coating layer according to the embodiment of the present invention may be a silicon film and/or a silicon oxide film, and the coating layer may have a thickness of 1 μm to 1 mm.

The film quality improvement step S500 is a step of improving the film quality of the coating layer formed on the shower head. When the precursor is vaporized and thus the coating layer is formed on the surface of the shower head, the second heating member in the shower head may be heated to apply heat to the coating layer. In this case, the shower head may heat the coating layer to 200° C. to 500° C. Through this step, the film quality of the coating layer formed on the shower head may be improved. Specifically, since heat is applied to the coating layer, the crystallinity of the coating layer may be improved, and the density thereof may be increased.

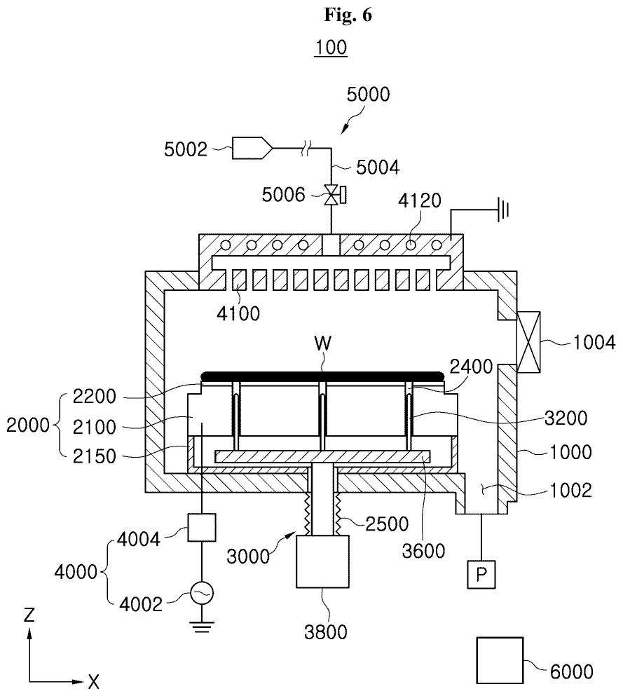

FIG. 6 is a view showing a substrate processing apparatus according to another embodiment of the present invention.

The substrate processing apparatus 100 shown in FIG. 6 differs from the substrate processing apparatus 100 shown in FIG. 3 only in the configuration of moving the substrate coated with the precursor to a region below the shower head using a lift pin assembly 3000 provided in the substrate support unit 2000.

Referring to FIG. 6, the substrate support unit 2000 may include a plurality of lift pins 3200 disposed at regular intervals in order to load and unload the substrate W. The substrate support unit 2000 may include a plurality of pin holes 2400 vertically penetrating the substrate support unit 2000 to allow the lift pins 3200 to move vertically therethrough. The lift pins 3200 may be coupled to lift pin holders (not shown), and the lift pin holders may be fixedly coupled to a lift pin support member 3600. A lift pin driving unit 3800 may raise and lower the lift pin support member 3600. Due to operation of the lift pin driving unit 3800, the lift pin support member 3600 may move vertically, and accordingly, the lift pins 3200 may move along the pin holes 2400. The lift pin driving unit 3800 may employ a hydraulic cylinder, a pneumatic cylinder, or the like. However, this embodiment is not limited thereto.

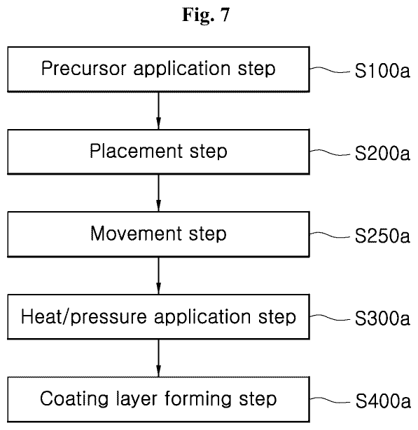

FIG. 7 is a flowchart showing a shower head coating method according to another embodiment of the present invention. The substrate processing apparatus shown in FIG. 6 may be used to perform the shower head coating method shown in FIG. 7.

Referring to FIG. 7, the shower head coating method according to the other embodiment of the present invention may include a precursor application step S100a of applying a precursor to a substrate, a placement step S200a of placing the substrate coated with the precursor in a processing space in a chamber, a heat/pressure application step S300a of applying heat and pressure to the substrate coated with the precursor, and a coating layer forming step S400a of forming a coating layer on a shower head. The shower head coating method shown in FIG. 7 does not include the film quality improvement step S500, unlike the shower head coating method shown in FIGS. 4 and 5.

Since the precursor application step S100a and the placement step S200a are identical to those of the method described above with reference to FIGS. 4 and 5, descriptions thereof will be omitted. The placement step S200a may include a movement step S250a of moving the substrate. However, the movement step S250a shown in FIG. 7 differs from that shown in FIGS. 4 and 5 in that the lift pin assembly is used to move the substrate coated with the precursor to a position spaced a predetermined distance from the shower head.

In the heat/pressure application step S300a, the second heating member of the shower head may be used in order to apply heat to the substrate. The heating temperature may be varied depending on the type of precursor applied to the substrate. According to the other embodiment of the present invention, the shower head may be in the temperature range of 200° C. to 500° C. It is also possible to apply pressure to the substrate simultaneously with applying heat thereto. In order to apply pressure to the substrate, the pressure in the chamber may be controlled. In this case, the pressure applied to the substrate may be controlled to be normal pressure to 0.01 torr. When both heat and pressure are applied to the substrate coated with the precursor, the precursor applied to the substrate may be vaporized.

The coating layer forming step S400a is a step of forming a coating layer on the shower head. The precursor on the substrate coated with the precursor may be vaporized in the heat/pressure application step S300a, and the vaporized precursor may form a coating layer on the shower head. The second heating member of the shower head may continuously apply heat. Thus, the film quality may be improved simultaneously when the coating layer is formed on the shower head. Therefore, the film quality improvement step S500 shown in FIGS. 4 and 5 is not necessary. The coating layer according to the other embodiment of the present invention may be a silicon film and/or a silicon oxide film, and the coating layer may have a thickness of 1 μm to 1 mm.

As described above, the substrate coated with a precursor may be placed in the substrate processing apparatus, and then heat and pressure may be applied to the substrate, whereby a coating layer may be formed on the shower head. In more detail, a precursor may be applied to the substrate in the substrate coating apparatus, and then the substrate coated with the precursor may be placed in the substrate processing apparatus, with a result that a coating layer may be formed on the shower head. Accordingly, the shower head may be prevented from being damaged by plasma. In addition, since the coating layer is formed on the shower head damaged by plasma, the shower head may be restored to have the original thickness thereof. As a result, damage to the shower head may be quickly repaired, and the frequency of exchanging the shower head may be reduced, leading to reduction in exchange cost.

As is apparent from the above description, according to the present invention, a precursor is applied to a substrate, and the precursor applied to the substrate is vaporized, thereby forming a coating layer on a shower head.

In addition, since the coating layer is formed on the shower head, it is possible to prevent damage to the shower head due to plasma.

The effects achievable through the present invention are not limited to the above-mentioned effects, and other effects not mentioned herein will be clearly understood by those skilled in the art from the above description.

It will be apparent to those skilled in the art that various changes in form and details may be made without departing from the essential characteristics of the invention set forth herein. Accordingly, the above detailed description is not intended to be construed to limit the invention in all aspects and to be considered by way of example. The scope of the invention should be determined by reasonable interpretation of the appended claims and all equivalent modifications made without departing from the invention should be included in the following claims.

What is claimed is:

1. A semiconductor manufacturing facility comprising:
an index block comprising a carrier configured to store a substrate coated with a precursor;
a processing block comprising a substrate processing apparatus configured to perform processing on the substrate; and
a substrate transferring block comprising a substrate transferring robot configured to load or unload the substrate,
wherein the substrate processing apparatus comprises:
a chamber comprising a processing space defined therein;
a substrate support unit disposed in the processing space and comprising a first heating member configured to support and heat the substrate coated with the precursor;
a gas supply unit configured to supply gas to the processing space;
a plasma generation unit configured to convert the supplied gas into plasma;
a shower head configured to supply the supplied gas to the processing space; and
a controller configured to control the gas supply unit and the plasma generation unit, and
wherein the controller controls the first heating member to heat the substrate supported by the substrate support unit so that the precursor applied to the substrate is vaporized and a coating layer is formed on the shower head.

2. The semiconductor manufacturing facility according to claim 1, wherein the shower head comprises a second heating member.

3. The semiconductor manufacturing facility according to claim 2, wherein the controller controls the second heating member of the shower head to apply heat to the coating layer formed on the shower head.

4. The semiconductor manufacturing facility according to claim 2, wherein the first heating member of the substrate support unit heats the substrate to 200° C. to 500° C., and
wherein the second heating member of the shower head heats the coating layer formed on the shower head to 200° C. to 500° C.

5. The semiconductor manufacturing facility according to claim 1, wherein the coating layer formed on the shower head is a silicon film or a silicon oxide film.

6. The semiconductor manufacturing facility according to claim 1, wherein the substrate support unit further comprises a driving unit and a lift pin assembly configured to raise and lower the substrate.

7. The semiconductor manufacturing facility according to claim 6, wherein the controller controls the driving unit to raise the substrate coated with the precursor toward the shower head, and controls the first heating member to vaporize the precursor applied to the substrate raised toward the shower head.

8. The semiconductor manufacturing facility according to claim 1, wherein the precursor comprises silane or siloxane.

9. The semiconductor manufacturing facility according to claim 8, wherein the precursor comprising silane is a precursor represented by Formula 1: 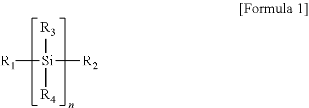
wherein R1, R2, R3, and R4 each is independently selected from the group consisting of H, OH, and a C1-C6 alkyl or alkenyl group, and n is in a range of 1 to 2,000 (1≤n≤2,000).

10. The semiconductor manufacturing facility according to claim 8, wherein the precursor comprising siloxane is a precursor represented by Formula 2: 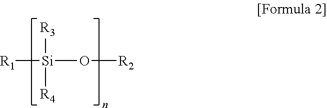
wherein R1, R2, R3, and R4 each is independently selected from the group consisting of H, OH, and a C1-C6 alkyl or alkenyl group, and n is in a range of 1 to 2,000 (1≤n≤2,000).

11. A shower head coating method comprising:
a precursor application step of applying a precursor to a substrate;
a placement step of placing the substrate coated with the precursor in a processing space in a chamber;
a heat/pressure application step of applying heat and pressure to the substrate coated with the precursor;
a coating layer forming step of vaporizing the precursor to form a coating layer on a shower head disposed so as to face the substrate; and
a film quality improvement step of heating the shower head to apply heat to the coating layer.

12. The shower head coating method according to claim 11, wherein the precursor in the precursor application step comprises silane or siloxane.

13. The shower head coating method according to claim 12, wherein the precursor comprising silane is a precursor represented by Formula 1: 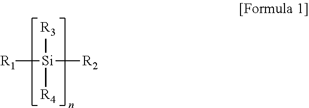
wherein R1, R2, R3, and R4 each is independently selected from the group consisting of H, OH, and a C1-C6 alkyl or alkenyl group, and n is in a range of 1 to 2,000 (1≤n≤2,000).

14. The shower head coating method according to claim 12, wherein the precursor comprising siloxane is a precursor represented by Formula 2: 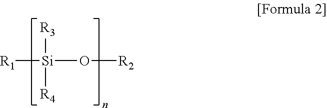
wherein R1, R2, R3, and R4 each is independently selected from the group consisting of H, OH, and a C1-C6 alkyl or alkenyl group, and n is in a range of 1 to 2,000 (1≤n≤2,000).

15. The shower head coating method according to claim 11, wherein the placement step comprises a movement step of moving the substrate coated with the precursor to a position facing the shower head.

16. The shower head coating method according to claim 11, wherein, in the heat/pressure application step, the heat applied to the substrate ranges from 200° C. to 500° C., and the pressure applied to the substrate ranges from normal pressure to 0.01 torr.

17. The shower head coating method according to claim 11, wherein the coating layer formed in the coating layer forming step is a silicon film or a silicon oxide film.

18. The shower head coating method according to claim 17, wherein the coating layer has a thickness of 1 μm to 1 mm.

19. The shower head coating method according to claim 11, wherein, in the film quality improvement step, the coating layer is heated to 200° C. to 500° C.

20. A semiconductor manufacturing facility comprising:
a carrier configured to store a substrate having a precursor applied to an upper surface thereof;
an index block comprising a load port configured to allow the carrier storing the substrate to be seated thereon and an index frame provided with an index robot configured to withdraw the substrate from the carrier seated on the load port;
a load lock chamber configured to temporarily store the substrate transferred from the index robot;
a processing block comprising a substrate processing apparatus configured to perform processing on the substrate; and
a substrate transferring block comprising a substrate transferring robot configured to load the substrate transferred from the load lock chamber into the substrate processing apparatus or to transfer the substrate unloaded from the substrate processing apparatus to the load lock chamber,
wherein the substrate processing apparatus comprises:
a chamber comprising a processing space defined therein;
a substrate support unit disposed in the processing space, the substrate support unit being configured to support the substrate coated with the precursor transferred from the substrate transferring robot;
a first heating member configured to heat the substrate coated with the precursor;
a gas supply unit configured to supply gas to the processing space;
a plasma generation unit configured to convert the supplied gas into plasma;
a shower head configured to supply the supplied gas to the processing space;
a driving unit configured to raise the substrate support unit or the substrate supported on the substrate support unit toward the shower head; and
a controller, and
wherein, when the substrate coated with the precursor is transferred to the substrate support unit, the controller controls the driving unit to raise the substrate coated with the precursor toward the shower head, and controls the first heating member so that the precursor applied to the substrate is vaporized and a coating layer is formed on the shower head.
